(19) United States
(12) Patent Application Publication
(10) Pub. No.: US 2019/0055846 A1
(43) Pub. Date: Feb. 21, 2019

(54) Thermal-barrier coating

(71) Applicant: The Trustees of Columbia University in the City of New York, New York, NY (US)

(72) Inventor: Arvind Narayanaswamy, New York, NY (US)

(21) Appl. No.: 15/998,737

(22) Filed: Aug. 16, 2018

Related U.S. Application Data
(60) Provisional application No. 62/546,228, filed on Aug. 16, 2017.

(51) Int. Cl. F01D 5/28; C23C 14/06; C23C 14/08; C23C 14/34; C23C 14/30; C23C 16/40; C23C 16/455; F01D 25/12

(52) U.S. Cl. CPC F01D 5/288; F05D 2300/2285; C23C 14/083; C23C 14/081; C23C 14/34; C23C 14/30; C23C 16/403; C23C 16/405; C23C 16/45525; F01D 25/12; F05D 2220/32; F05D 2230/90; F05D 2240/30; F05D 2260/20; F05D 2300/2284; C23C 14/0641

(57) ABSTRACT

Thermal-barrier coatings for protecting a substrate from heat include a nitride layer, with the nitride layer including an interstitial nitride of a transition metal. In some embodiments, the nitride layer may include, for example, titanium nitride, niobium nitride, hafnium nitride, vanadium nitride, or zirconium nitride. The implementations further include a method comprising providing a substrate for use in assembling structures (e.g., a turbine blade) configured to be exposed to high temperature conditions, and applying a coating to the substrate, with the coating comprising a nitride layer, and with the nitride layer comprising transition-metal nitride.

### CROSS-REFERENCE TO RELATED APPLICATIONS

This application claims the benefit of the Aug. 16, 2017 priority date of U.S. Provisional Application 62/546,228, the content of which is herein incorporated by reference in its entirety.

### BACKGROUND

The present disclosure relates thermal barrier coating that are used to protect structures (e.g., such as gas turbines) from high temperature conditions.

Gas turbines are frequently used for generating electricity and for industrial uses. At sea, gas turbines find applications in marine propulsion. Gas turbines are particularly conspicuous to the public in aviation, where they form the basis for typical jet engines. Gas turbines become very hot during operation. In modern engines, turbine inlet temperatures approach 1900 K.

Known ways of protecting these parts from extreme heat include elaborate cooling systems that pass cooling fluids within or over a protected region. Another known method is to coat the region to be protected with insulating materials that slow down the transfer of heat between the flames and the regions needing protection.

### SUMMARY

The embodiments described herein pertain to implementations, including choice of materials, of thin film (and optionally multilayer) structures that reflect most of the thermal radiation from combustion gases at temperature around 2000 K.

Embodiments of a multilayer thin film structure include a bilayer structure with one film composed of any of the following materials: titanium nitride, zirconium nitride, hafnium nitride, niobium nitride, or vanadium nitride. A second film composed of alumina or yttrium aluminum garnet (YAG) is deposited on the nitride layer. The alumina or yttrium aluminum garnet layer is exposed to the combustion gases. These two films are deposited atop other ceramic and metallic films that constitute a thermal-barrier coating (“TBC”). The nitride films can be deposited by, for example, sputtering or by electron beam deposition. Alumina and yttrium aluminum garnet films can be deposited by sputtering or atomic layer deposition. Other ways to deposit the films may also be used.

The implementations described herein can be used to shield against thermal radiation for wavelengths in part of the visible spectrum and the infrared spectrum by reflecting waves in those wavelengths. Because of the protective coating of alumina or yttrium aluminum garnet, the structures described herein are well-suited for protecting metallic surfaces from thermal radiation emitted by combustion gases. Hence, the implementations described herein will be useful for thermally protective coatings on gas turbine components and can be applied to gas turbines in jet engines, whether commercial or military, and power generation, whether terrestrial or marine. The implementations described herein can also be used to protect surfaces within the main combustion chamber of space shuttles and in internal combustion engines.

Thermal-barrier coatings described herein rely on the use of certain transition-metal nitrides to protect metal parts of a gas turbine from excessive heat. Such transition-metal nitrides have optical and conductive properties that differ significantly from those of oxide-based ceramics. These differences promote their ability to function as a thermal barrier coating.

In one aspect, the disclosed embodiments feature an apparatus that includes a substrate and a coating that includes a nitride layer. This nitride layer includes an interstitial nitride of a transition metal. Among these are embodiments in which the nitride layer includes titanium nitride, niobium nitride, hafnium nitride, vanadium nitride, zirconium nitride, and combinations thereof. Other embodiments include those in which the nitride layer is substantially 100 nanometers thick.

In some embodiments, the coating also has a top layer. One face of the top layer is exposed and the other faces the nitride. Suitable materials for this top layer include alumina and yttrium aluminum. Embodiments also include those in which the top layer has a diffusivity to oxygen gas that is below 10¹³ square centimeters per second at 1500K.

Other embodiments feature a layer between the nitride layer and the substrate. A suitable layer is one made of a refractory oxide ceramic. In other embodiments, this layer comprises 7YSX.

Some embodiments include a gas turbine, with the substrate being a constituent of the gas turbine, such as a turbine blade.

In other embodiments, the substrate is nickel-based super alloy.

In another aspect, a method includes providing a substrate for use in assembling structures exposed to high temperature conditions, and applying a coating to a substrate, with the coating comprising a nitride layer, and with the nitride layer comprising transition-metal nitride.

Some practices of the method are those in which applying a coating further includes applying a top layer of oxygen-impervious material above the nitride layer, with the top layer having a face exposed to oxygen and a face that faces the nitride layer. Among these are practices in which the top layer has a diffusivity to oxygen gas that is below 10¹³ square centimeters per second at 1500K.

Also among the practices are those in which applying a coating to a substrate includes applying a coating to turbine blades of a gas turbine.

Yet other practices include exposing the coating to combustion gases that radiate as a black body at a temperature of between 1800K and 2100K and causing at least a hundredfold reduction in radiative load at the substrate.

In another aspect, a thermal-barrier coating is provided that is configured to protect a substrate from heat. The thermal-barrier coating includes a first layer that comprises a transition-metal nitride ceramic.

In some embodiments, a second layer is disposed on the first layer. The second layer is a top layer having an exposed first face and a second face facing the first layer.

Embodiments include those in which the transition-metal nitride ceramic comprises a nitride of a transition metal.

Also among the embodiments are those in which the transition-metal nitride comprises titanium nitride, those in which it comprises niobium nitride, those in which it comprises hafnium nitride, those in which it comprises vanadium nitride, and those in which it comprises zirconium nitride. Niobium nitride, for example, also exhibits enhanced phonon-scattering ability.

Some embodiments feature a structure disposed between the first layer and the substrate. These include embodiments in which a third layer comprises a refractory oxide ceramic compound, such as seven percent yttria-stabilized zirconia (“7YSZ”).

Further embodiments include those in which the second layer comprises alumina and those in which it comprises yttrium aluminum.

Some embodiments include a gas turbine. In these embodiments, the substrate is part of the gas turbine.

Yet other embodiments include an engine. In these embodiments, the substrate is part of the engine.

Other features and advantages of the invention are apparent from the following description, and from the claims.

### BRIEF DESCRIPTION OF THE DRAWINGS

These and other feature and advantages of the subject matter described herein will be apparent from the following detailed description and the accompanying figures, in which

FIG. 1 is an example diagram of an engine to which the thermal barrier coatings described herein may be applied.

FIG. 2 is a diagram showing example layers that may be used to constitute a coating for use, for example, in the engine of FIG. 1.

FIGS. 3A and B include graphs showing wavelength-dependent real (n) and imaginary (k) parts of refractive index of different materials that could act as radiative barriers in thermal-barrier coatings.

FIG. 3C is a graph illustrating a transmitted radiative flux into a metallic substrate as a function of wavelength

FIG. 4 is a flowchart of a particular procedure for protecting substrate materials from extreme heat conditions.

Like reference symbols in the various drawings indicate like elements.

### DETAILED DESCRIPTION

Described herein are implementations for thin film thermal barrier coating (TBC) structures that can reflect a substantial portion (e.g., most, in some circumstances) of the thermal radiation from combustion gases at a temperature of around 2000 K. The thermal-barrier coatings described herein may be multilayer structures (e.g., a minimum of two layers). Such multilayer structures may include alternating films of interstitial metallic nitrides and alumina or yttrium aluminum garnet. In some embodiments, film deposition techniques (sputtering or electron beam deposition for nitride films, sputtering or atomic layer deposition for alumina or yttrium aluminum garnet films) may be used to deposit the thermal-barrier coating. The implementations described herein can be used as a shield or reflector for thermal radiation for wavelengths in part of the visible spectrum and the infrared spectrum, and potentially can decrease the radiative load on the underlying metal substrate by almost two orders of magnitude, leading to reduced cooling and greater efficiency

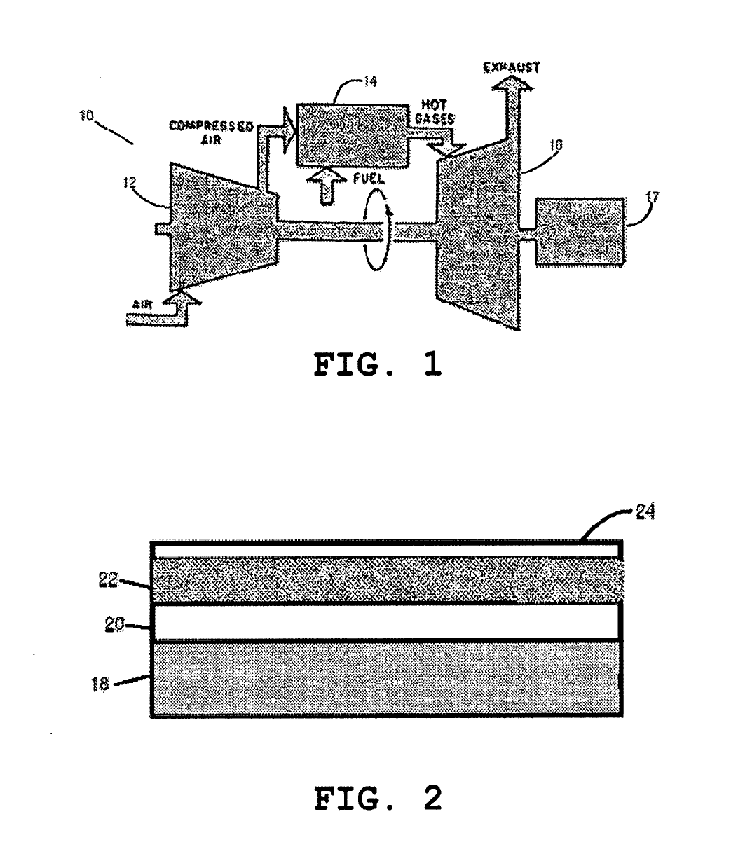

FIG. 1 shows an engine 10 having a compressor 12, a combustion chamber 14, and a turbine 16. The engine 10 operates by having the compressor 12 compress gas into which fuel has been added. The fuel is made to burn in the compressed gas. The gas is allowed to expand and cool as it passes through the turbine 16 on its way out of the engine 10. As it does so, it causes the turbine 16 to turn. This turns a load 17, such as a generator, that is connected to the turbine 16. In this way, the engine 10 converts heat energy in the gas into another form of energy. In the case of a generator, that form of energy is electrical energy. Other systems and apparatus that are configured to burn fuel or gas, and create (or otherwise be exposed to) high temperature (and pressure) conditions are also covered by the present disclosure.

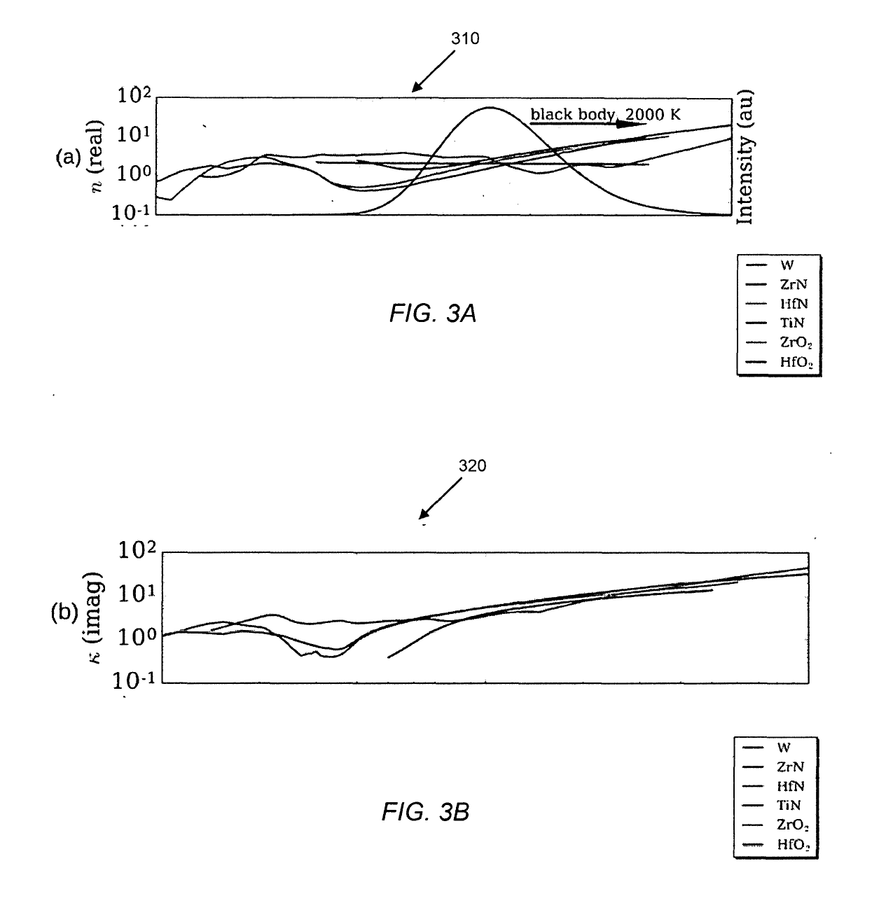

FIG. 2 shows a substrate 18 that is to be protected from the electromagnetic waves within, for example, the engine 10 of FIG. 1. The substrate 18 is typically a part of the engine 10. For example, the substrate 18 might be a blade or a wall of a combustion chamber 14 or a blade on the turbine 16. In a typical application, the electromagnetic waves have wavelengths between five microns and half a micron.

Disposed on a surface of the substrate 18 is a first layer 20 made of a material with low heat conductivity. Examples of such materials include refractory oxide ceramic compounds. Such materials are chosen for the efficiency with which they scatter phonons and photons. A typical material is 7YSZ, or zirconium stabilized by 7% yttrium.

Disposed on a top surface of the first layer 20 (the surface not in contact with the substrate) is a second layer 22 that is made of an interstitial transition-metal nitride. Examples of suitable nitrides are titanium nitride, zirconium nitride, hafnium nitride, niobium nitride, and vanadium nitride. These layers may be applied by sputtering or electron beam deposition. A typical thickness for this nitride layer is about 100 nanometers.

Disposed on the second layer 22 is a third layer 24 made of a material that suppresses the ability of the material in the second layer 22 to engage in chemical reactions. A suitable material for the third layer 24 is alumina or yttrium aluminum garnet. This third layer may be deposited via sputtering or atomic layer deposition. A typical thickness for this third layer 24 is about ten micrometers.

The particular order of layers shown is only one of many possible orders. For example, it is also possible to place the second layer 22 between the substrate 18 and the third layer 24 with the first layer 20 being the outermost layer. Another embodiment has the second layer 22 between the substrate 18 and the first layer 20 with the third layer 24 being the outermost layer.

Transition-metal ceramics are generally better conductors of heat than oxide ceramics because they retain more of their metallic properties. They are also highly efficient at scattering and reflecting infrared radiation. As such, they tend to suppress heat transfer by radiation from hot combustion products. This tends to reduce the heat load passing through the oxide ceramic layer 20 as well as the region to be protected (e.g., the substrate 18 of FIG. 2).

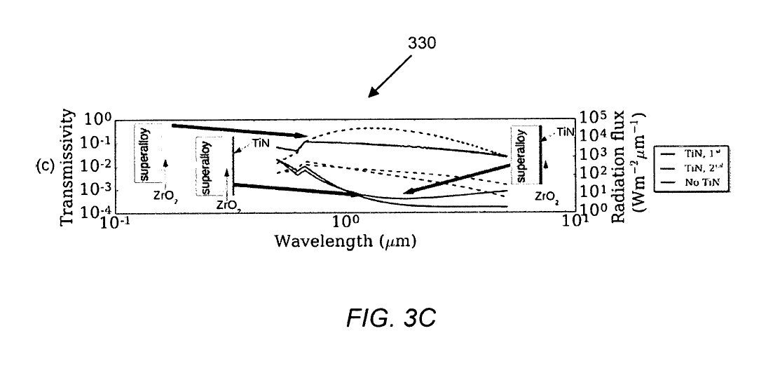

The implementations described herein, which comprise interstitial nitride ceramics, such as zirconium nitride, hafnium nitride, titanium nitride, and niobium nitride, provide improved thermal radiation barriers. Particularly, the interstitial nitrides described herein are “metallic” ceramics and have metal-like electrical conductivity as well as desirable optical properties. The refractive index for zirconium nitride, hafnium nitride, titanium nitride, and tungsten, which is a metal having a particularly high melting point, are shown in FIGS. 3A and 3B, which provides graphs (310 and 320, respectively) of wavelength-dependent real and imaginary parts of refractive indices of different materials that are suitable for use as radiative barriers in thermal-barrier coatings. The real and imaginary parts of zirconium nitride, hafnium nitride, and titanium nitride resemble those of tungsten.

To see how the metallic nitrides described herein might act as radiation shields in thermal-barrier coatings, the radiative heat flux that flows into a superalloy substrate that is capped with a thermal-barrier coating was simulated. Since the bond-coat is also metallic, for purposes of electromagnetic simulations, it was assumed that the dielectric function of the superalloy base and the bond-coat were substantially similar to the dielectric function of nickel. The bond-coat included an aluminum oxide (Al₂O₃) thermally-grown oxide layer. The oxide layer was simplified by considering only a 100-micrometer layer of zirconium dioxide. The region adjacent to the thermal-barrier coating is assumed to be filled with combustion gases, which are approximated collectively as a blackbody at 2000 K.

With reference to graph 330 of FIG. 3, the transmitted radiative flux into the metallic substrate is plotted as a function of wavelength. Comparison of radiative flux transmitted into the superalloy substrate with a thermal-barrier coating that has, for example, a titanium nitride layer of thickness 100 nanometers (between zirconium dioxide and the combustion gases or between the superalloy substrate and the zirconium dioxide layer) and a thermal-barrier coating without the titanium nitride layer shows that the titanium nitride layer can decrease the radiative flux by almost two orders of magnitude. Integration over all wavelengths show that transmitted radiative flux can be reduced to 1% of its value (the magnitude of the transmitted radiative flux is ≈0.06 megawatts per square meter at 2000 K and 0.16 megawatts per square meter at 2500 K) by adding the titanium nitride layer. A similar (almost 100-fold) reduction can be obtained for zirconium nitride or hafnium nitride films of thickness 100 nanometers.

Although optical data is useful for identifying suitable materials for use as radiation shields, it is not the only factor of significance.

Some relevant properties of interstitial nitrides as well as 7YSZ and yttrium aluminum garnet are given in Table 1 provided below.

TABLE 1
Properties of Refractory Ceramics for use in thermal
barrier coatings

| | | | α or | | |
|---|---|---|---|---|---|
| | Melting | K | CTE | ρ | |
| Material | point | (Wm⁻¹K⁻¹) | (×10⁻⁶ K⁻¹) | (μΩ · cm) | Comments |
| ZrN | 2980 | ≈24 | 7.24 | 7-21 | K >> |
| | | | | | k_{YSZ;} α < |
| | | | | | α_{YSZ}; |
| | | | | | low ρ |
| | | | | | → More |
| | | | | | reflective |
| | | | | | than NbN |
| HfN | 3387 | ≈20 | 6.9 | 33 | Same as |
| | | | | | above. |
| TiN | 2950 | ≈27 | 9.35 | 10-30 | K >> |
| | | | | | k_{YSZ;} α ≈ |
| | | | | | α_{YSZ}; |
| | | | | | low ρ -> |
| | | | | | More |
| | | | | | reflective |
| | | | | | than NbN |
| NbN | 2630 | 3.8 | 10.1 | 58 | K ≈ k_{YSZ;} |
| | | | | | α ≈ α_{YSZ} |
| 7YSZ | 2710 | 2.3 | 10.7 | | |
| YAG | 1960 | 3.0 | 9.1 | | |

The three nitrides zirconium nitride, hafnium nitride, and titanium nitride have relatively lower electrical resistivities, indicating that they may be better reflectors of IR electromagnetic waves and thermal radiation from combustion gases. The CTE (coefficient of thermal expansion) for zirconium nitride and hafnium nitride are lower than that of 7YSZ. The CTE for titanium nitride and niobium nitride are comparable with that of 7YSZ and yttrium aluminum garnet. The thermal conductivity of niobium nitride is lower than that of other interstitial nitrides. Thus, niobium nitride seems to possess all the thermophysical properties that a thermal-barrier coatings material should possess.

The physical and chemical stability of nitride films are also of importance in selecting suitable materials. There are at least two types of stability of interest: (1) stability under thermal cycling, and (2) stability in the presence of combustion products and oxygen. Some information is available regarding the stability of titanium nitride when subjected to thermal cycling. Films were subjected to temperature changes under vacuum conditions remain stable. In particular, although reflectivity tends to diminish at high temperatures, it remains sufficient to be practical for protection against high radiation loads.

One way to promote the ability of a nitride film (e.g., titanium nitride, zirconium nitride, hafnium nitride, or niobium nitride) to function for extended periods at high temperatures in the presence of oxygen/combustion gases is by protecting the nitride film with another film that is optically transparent but opaque to the passage of oxygen. Some ceramic oxide materials described herein are optically transparent in the 0.5-5 μm wavelength range. The transparency to oxygen can be gauged from the magnitude of the self-diffusion coefficient of oxygen in the material.

The temperature-dependent self-diffusion coefficient of oxygen can be represented as D_{O2/M}=A exp(−ΔE/RT). The values of A, ΔE, and D at 1500 K for diffusion of O₂ through YSZ, yttrium aluminum garnet, and Al₂O₃ are given in Table 2 (below). In Table 2, the diffusivity D is of the form A exp(−ΔE/RT) with R, the universal gas constant, in joules per mole per degree Kelvin and T is the absolute temperature. At a representative temperature of T=1500 K, the diffusivity values computed for different materials included D_{O2/YSZ}=1.5×10⁻⁶ square centimeters per second, DO2/YAG=2.58×10⁻¹⁴ square centimeters per second, and D_{O2/Al2O3}=2.9×10²⁰ square centimeters per second (for a single crystal), and 1.9×10⁻¹⁶ square centimeters per second (for a polycrystalline). The lower diffusivity of O₂ through Al₂O₃ and YAG thus suggests a process of ensuring that metal nitride films are not affected by the ambient conditions, namely, by using interstitial metal nitride capped by Al₂O₃ or YAG films.

TABLE 2
Diffusivity of oxygen in some refractory ceramics
for use in thermal barrier coatings.

| | Prefactor | ΔE | D at 1500 K | |
|---|---|---|---|---|
| Material | A (cm² · s⁻¹) | (J · mol⁻¹) | (cm² · s⁻¹) | Comments |
| O₂ in YSZ | 3.4 × 10⁻³ | 95400 | 1.5 × 10⁻⁶ | Single crystal |
| | | | | sample |
| O₂ in YAG | 5.27 × 10⁻³ | 325000 | 2.58 × 10⁻¹⁴ | Single crystal |
| | | | | sample |
| O₂ in | 1.12 × 10³ | 648520 | 2.9 × 10⁻²⁰ | Single crystal |
| Al₂O₃ | | | | sample |
| O₂ in | 1.9 × 10³ | 635970 | 1.35 × 10⁻¹⁹ | Single crystal |
| Al₂O₃ | | | | sample |
| O₂ in | 2.0 | 460240 | 1.9 × 10⁻¹⁶ | Polycrystalline |
| Al₂O₃ | | | | sample |

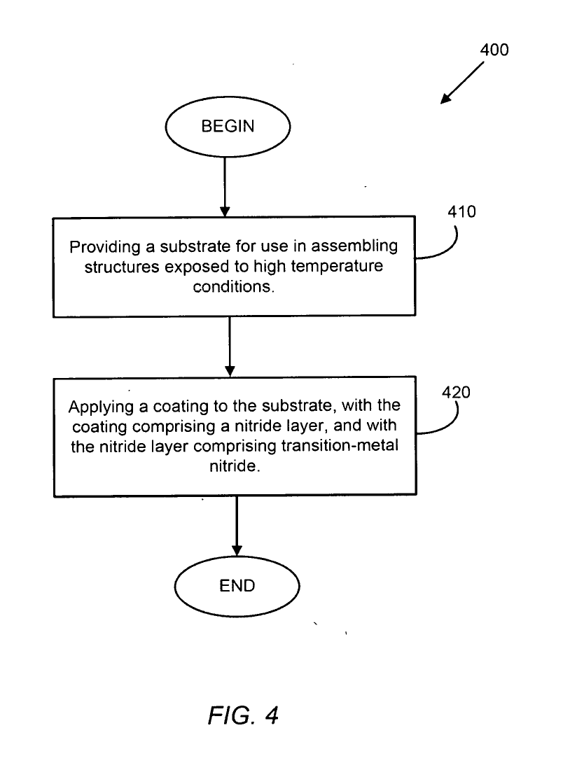

FIG. 4 shows a flowchart of one example of a method 400 of protecting a substrate material from extreme heat. The method 400 includes providing a substrate for use in assembling a structure (e.g., a gas turbine blade) that is expected to be exposed to high temperatures (step 410). The method 400 further includes applying a coating (such as the coating depicted in FIG. 2) to a substrate (such as the substrate 18 of FIG. 2), with the coating comprising a nitride layer, and with that nitride layer including transition-metal nitride (step 420). Examples of a nitride layer for use as the coating to be applied to the target substrate include niobium nitride, hafnium nitride, vanadium nitride, and zirconium nitride.

In some embodiments, applying the coating may further include applying a top layer of oxygen-impervious material disposed on the nitride layer. Such a top layer may have a face exposed to oxygen and a face that faces the nitride layer, with the top layer having a diffusivity to oxygen gas that is below 10¹³ square centimeters per second at 1500K. In some embodiments, applying the coating to the substrate may include applying the coating to turbine blades of a gas turbine. In some embodiments, the method 400 may further include exposing the coating to combustion gases that radiate as a black body at a temperature of between 1800K and 2100K and causing at least a hundredfold reduction in radiative load at said substrate.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of +20% or ±10%, ±5%, or +0.1% from the specified value, as such variations are appropriate in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate in the context of the systems, devices, circuits, methods, and other implementations described herein.

As used herein, including in the claims, “or” as used in a list of items prefaced by “at least one of” or “one or more of” indicates a disjunctive list such that, for example, a list of “at least one of A, B, or C” means A or B or C or AB or AC or BC or ABC (i.e., A and B and C), or combinations with more than one feature (e.g., AA, AAB, ABBC, etc.). Also, as used herein, unless otherwise stated, a statement that a function or operation is “based on” an item or condition means that the function or operation is based on the stated item or condition and may be based on one or more items and/or conditions in addition to the stated item or condition.

Although particular embodiments have been disclosed herein in detail, this has been done by way of example for purposes of illustration only and is not intended to be limit the scope of the invention, which is defined by the scope of the appended claims. Features of the disclosed embodiments can be combined, rearranged, etc., within the scope of the invention to produce more embodiments. Some other aspects, advantages, and modifications are considered to be within the scope of the claims provided below. The claims presented are representative of at least some of the embodiments and features disclosed herein. Other unclaimed embodiments and features are also contemplated.

1. An apparatus comprising a substrate and a coating that comprises a nitride layer, wherein said nitride layer comprises an interstitial nitride of a transition metal.

2. The apparatus of claim 1, further comprising a top layer having an exposed face and a face that faces said nitride.

3. The apparatus of claim 1, wherein said nitride layer comprises titanium nitride.

4. The apparatus of claim 1, wherein said nitride layer comprises niobium nitride.

5. The apparatus of claim 1, wherein said nitride layer comprises hafnium nitride.

6. The apparatus of claim 1, nitride layer comprises vanadium nitride.

7. The apparatus of claim 1, wherein said nitride comprises zirconium nitride.

8. The apparatus of claim 1, wherein said nitride layer has a thickness of 100 nanometers.

9. The apparatus of claim 1, further comprising a refractory oxide ceramic disposed between said nitride layer and said substrate.

10. The apparatus of claim 1, further comprising a layer of 7YSX disposed between said nitride layer and said substrate.

11. The apparatus of claim 1, further comprising an alumina layer that faces said nitride layer, wherein said alumina layer has an exposed face.

12. The apparatus of claim 1, further comprising an exposed layer of yttrium aluminum, wherein said nitride layer faces said yttrium aluminum.

13. The apparatus of claim 1, further comprising a gas turbine, wherein said substrate is part of a turbine blade.

14. The apparatus of claim 1, wherein said substrate is nickel-based super alloy.

15. The apparatus of claim 1, further comprising a top layer that that has a diffusivity to oxygen gas that is below 10¹³ square centimeters per second at 1500K wherein said top layer has an exposed face and a face that faces said nitride layer.

16. The apparatus of claim 1, wherein said nitride layer has a thickness of at least 100 nanometers.

17. A method comprising: providing a substrate for use in assembling structures exposed to high temperature conditions, and applying a coating to the substrate, wherein said coating comprises a nitride layer, and wherein said nitride layer comprises transition-metal nitride.

18. The method of claim 17, wherein applying a coating further comprises applying a top layer of oxygen-impervious material disposed on said nitride layer, wherein said top layer has a face exposed to oxygen and a face that faces said nitride layer, wherein said top layer has a diffusivity to oxygen gas that is below 10¹³ square centimeters per second at 1500K.

19. The method of claim 17, wherein applying a coating to a substrate comprises applying a coating to turbine blades of a gas turbine.

20. The method of claim 17, further comprising exposing said coating to combustion gases that radiate as a black body at a temperature of between 1800K and 2100K and causing at least a hundredfold reduction in radiative load at said substrate.
